(19) United States
(12) Patent Application Publication
(10) Pub. No.: US 2025/0328772 A1
(43) Pub. Date: Oct. 23, 2025

(54) METHOD AND COMPUTER DEVICE FOR DETERMINING THE EXPOSURE POSITION OF EXPOSURE TOOL

(71) Applicant: Winbond Electronics Corp., Taichung City (TW)

(72) Inventors: Erh-Ting HSIEH, Taichung City (TW); Li-Chien WANG, Taichung City (TW); Chun-Hsu CHEN, Taichung City (TW)

(73) Assignee: Winbond Electronics Corp., Taichung City (TW)

(21) Appl. No.: 19/097,639

(22) Filed: Apr. 1, 2025

(30) Foreign Application Priority Data
Apr. 17, 2024 (TW) 113114306

(51) Int. Cl. G06N 3/09; G06N 3/0464

(52) U.S. Cl. CPC G06N 3/09; G06N 3/0464

(57) ABSTRACT

A method for determining the exposure position of an exposure tool, performed by a computer device. The method includes training a regression model based on raw data of the exposure tool with a plurality of key factors that affect the actual offset value of the exposure tool. The method also includes using the trained regression model to calculate the predicted offset value based on the raw data. The method also includes compensating for the exposure position of the exposure tool based on the predicted offset value to adjust the exposure position of the exposure tool.

### CROSS REFERENCE TO RELATED APPLICATIONS

This application claims priority of Taiwan Patent Application No. 113114306 filed on Apr. 17, 2024, the entirety of which is incorporated by reference herein.

### BACKGROUND

### Technical Field

The present disclosure relates to a method for determining the exposure position of an exposure tool, and in particular it relates to a method for determining the exposure position of an exposure tool using artificial intelligence.

### Description of the Related Art

With the advancements in artificial intelligence (AI) computing, the applications of AI computing have become increasingly widespread. For example, neural network models are used for image analysis, speech analysis, natural language processing, and other neural network computations. As a result, various technical fields continue to invest in the research, development, and application of AI, and various machine learning algorithms, such as convolutional neural networks (CNN) and deep neural networks (DNN), are constantly being developed.

In conventional photolithography exposure tools, optical lenses are heated and expand when exposed to laser light for a long period of time, thereby changing their focal position and affecting exposure imaging and causing thermal aberrations. Generally, these thermal aberrations can be calculated and compensated for using a physical model built into the photolithography exposure tool. However, using a fixed physical model for calculations has limitations in scalability, highlighting the need to explore other methods to improve the calculation of thermal aberrations.

### BRIEF SUMMARY

In view of this, the embodiment of the present disclosure utilizes a machine learning algorithm to analyze the data of the exposure tool and constructs a regression model to improve the existing method for calculating thermal aberrations and address the scalability issues of the existing physical model.

The present disclosure provides a method for determining an exposure position of an exposure tool, performed by a computer device, and including training a regression model based on a raw data of the exposure tool with a plurality of key factors. The key factors affect an actual offset value of the exposure tool. The method further includes using the trained regression model to calculate a predicted offset value based on the raw data, and compensating for the exposure position of the exposure tool based on the predicted offset value to adjust the exposure position of the exposure tool.

The present disclosure provides a computer device implementing the above method. The computer device uses the predicted offset value obtained by the above method to compensate for the exposure position of the exposure tool.

### BRIEF DESCRIPTION OF THE DRAWINGS

FIG. 1 illustrates a simplified schematic diagram of the computer device according to the embodiments of the present disclosure.

FIG. 2 illustrates a schematic diagram of the thermal aberrations caused by the exposure tool.

FIG. 3 illustrates a flowchart of the method for determining the exposure position of the exposure tool according to the embodiments of the present disclosure.

FIG. 4 illustrates a block diagram of an exemplary method according to the embodiments of the present disclosure.

### DETAILED DESCRIPTION

The following description provides various embodiments of the present disclosure, but is not intended to limit the scope of the present disclosure. The actual scope of the present disclosure is defined by the claims of the patent application. In the embodiments listed below, the same reference numbers will be used to represent the same or similar components or elements. Furthermore, the numerical designations in this specification, such as “first,” “second,” etc., are for convenience of explanation and do not imply any sequential order.

The embodiment of the present disclosure implements a machine learning algorithm by a computer device. Based on the raw data obtained from the exposure tool, a plurality of key factors that actually affect the thermal offset of the exposure tool are selected. Then, a feature extraction model is used to extract features related to these key factors from the raw data, which are used to train a regression model. A loss function is subsequently applied to compute the loss value between the predicted offset value generated by the regression model and the actual offset value provided by the exposure tool. Based on this loss value, the parameters of the regression model are optimized to continuously improve the performance of the regression model, enabling the regression model to more accurately predict the thermal aberrations of the exposure tool as the number of training iterations or training time increases.

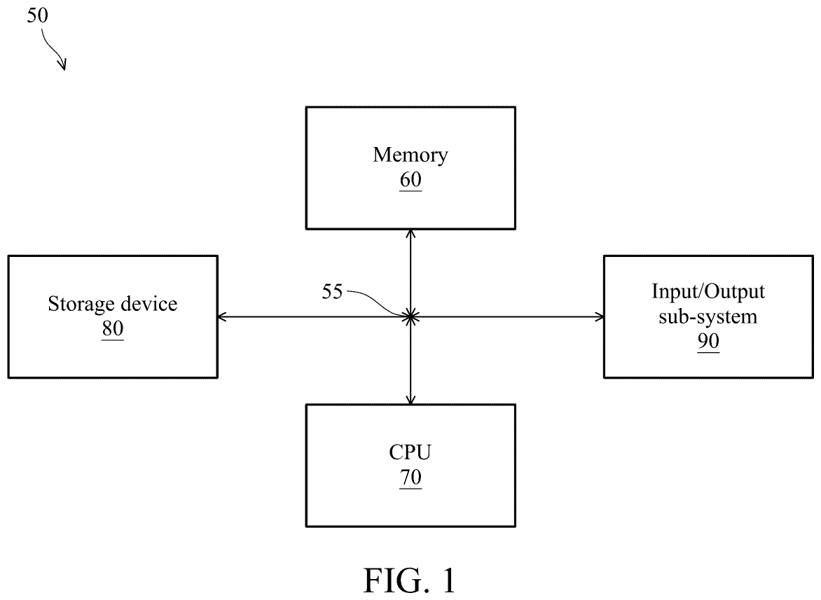

FIG. 1 illustrates a simplified schematic diagram of a computer device 50 according to the embodiment of the present disclosure. In an embodiment, the computer device 50 includes a memory 60, a central processing unit (CPU) 70, a storage device 80, and an input/output sub-system 90. These components communicate with each other through one or more communication buses or signal lines 55. It should be understood that the computer device 50 is merely one example of the computer device, and the computer device 50 may include more or fewer components than those illustrated, or may have a different component configuration. The components shown in FIG. 1 may be implemented in hardware, software, or a combination of both hardware and software, such as one or more signal processing integrated circuits (IC) and/or application-specific integrated circuits.

In the embodiment, the memory 60 may include high-speed random access memory and may also include non-volatile memory, such as a disk storage device, a flash memory device, or other non-volatile solid-state memory devices. Access to the memory 60 may be controlled by a memory controller, such as accessing the memory 60 through other components of the computer device 50 (e.g., CPU 70). In the embodiment of the present disclosure, the memory 60 may include a combination of applications or modules related to machine learning, such as method 100, which will be described in more detail below. The CPU 70 may perform various software programs and/or instruction sets stored in the memory 60 to implement various functions of the computer device 50 and process data stored in the storage device 80.

The CPU 70 is used to control the operation of the computer device 50. The CPU 70 provides the processing power required to perform the functions of the operating system, programs, user graphical interface, software, modules, applications, and the computer device 50. In the embodiment, the CPU 70 may include at least one processor. For example, the CPU 70 may include a general-purpose microprocessor, a combination of a general-purpose microprocessor and a specialized processor, and/or an associated chipset. Examples of combinations of the general-purpose microprocessors and the specialized processors include instruction set processors, graphics processors, image processors, and specialized microprocessors.

Information to be processed by the CPU 70 or information processed by the CPU 70 may be stored in the storage device 80. For example, the storage device 80 may store image data, experimental data, test data, and any other suitable data. In the embodiment, the storage device 80 may be a non-volatile memory, such as read-only memory (ROM), flash memory, hard disk, optical computer-readable media, magnetic computer-readable media, solid-state computer-readable media, and combinations thereof.

The input/output sub-system 90 may include an input controller, which may receive electronic signals from or transmit electronic signals to other input or output devices, such as to transmit or to receive data related to the exposure tool 10.

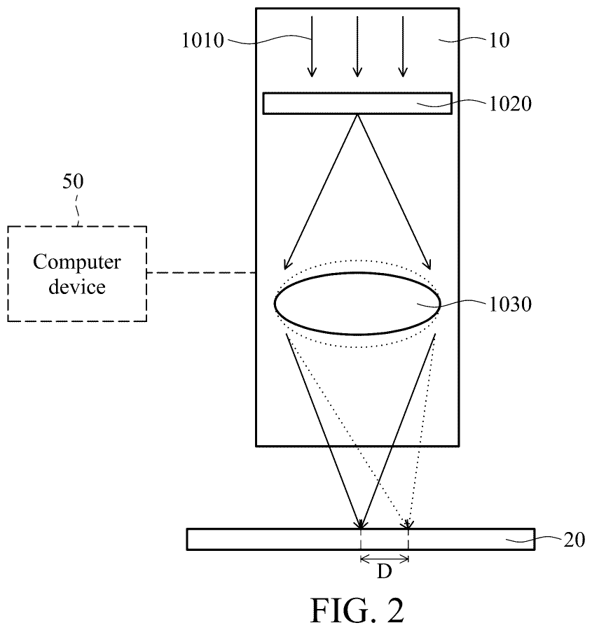

As shown in FIG. 2, generally, in the exposure tool 10, light 1010 passes through a mask 1020, causing diffraction, and is then focused onto the wafer 20 by the lens 1030. However, after a long period of time of exposure to high-energy light 1010 (e.g., laser light), the lens 1030 may thermally expand, thereby adversely shifting its focal position and causing a thermal aberration D, which results in a discrepancy between the intended and actual focus of the light 1010. In the embodiments of the present disclosure, by coupling the computer device 50 to the exposure tool 10, data related to the exposure tool 10 is input to the computer device 50 for machine learning analysis and training of a regression model to predict the value of the thermal aberration D.

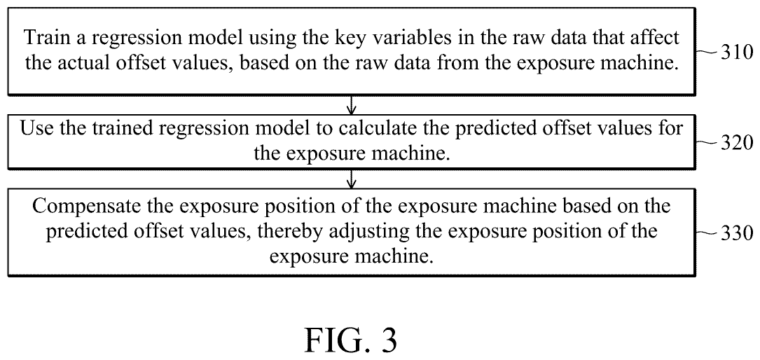

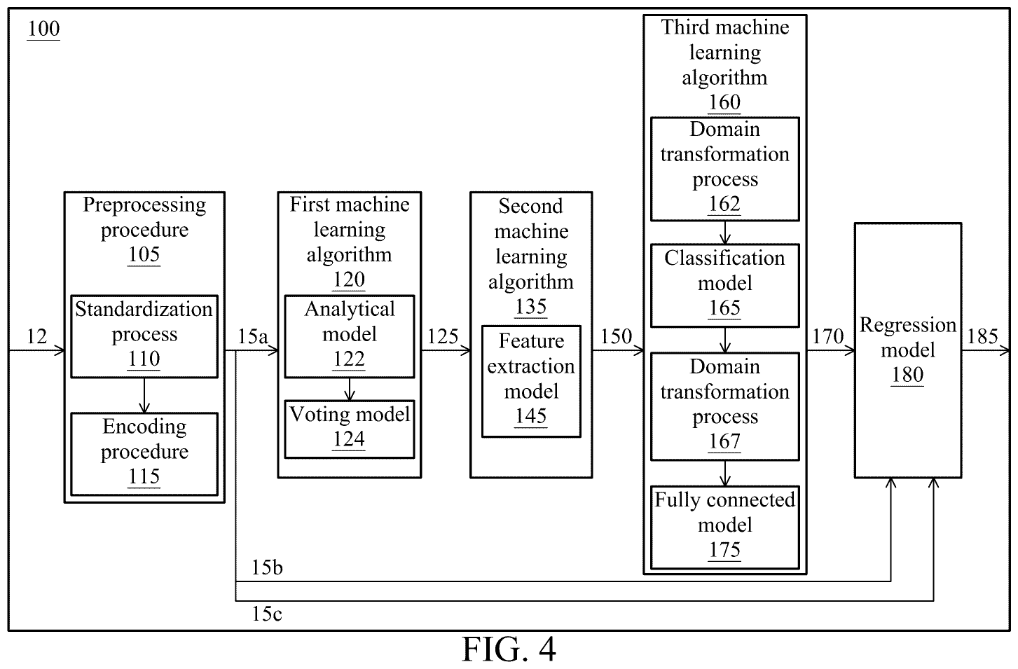

The following describes a method 100 for determining the exposure position of the exposure tool 10 in the embodiment of the present disclosure. As shown in FIG. 3, in step 310, a regression model 180 is trained based on the raw data 12 of the exposure tool 10, using data related to the key factors 125 in the raw data 12 that affect the actual offset value. In the embodiment, the method 100 may be implemented by the computer device 50 based on the raw data 12 of the exposure tool 10, more specifically, performed by the CPU 70 from the method 100 stored in the memory 60. In the embodiment, as shown in FIG. 4, the method 100 includes a preprocessing procedure 105. In the embodiment, the preprocessing procedure 105 further includes a normalization process 110 and an encoding procedure 115. The normalization process 110 ensures that no data in the raw data 12 is overlooked in subsequent steps due to differences in magnitude. For example, the normalization process 110 may scale the data in the raw data 12 (e.g., data with different units and magnitudes, such as temperature and pressure) to a value between 0 and 1 (e.g., the maximum temperature value is converted to 1, and the minimum temperature value is converted to 0). The encoding procedure 115 divides the data, which has undergone the normalization process 110, into different datasets. In the embodiment, a training dataset 15a, a validation dataset 15b, and a test dataset 15c may be obtained after performing the encoding procedure 115 through methods such as k-fold cross-validation. In the embodiment, the training dataset 15a undergoes further data processing for training the regression model 180, while the validation dataset 15b and the test dataset 15c are used for validating and testing the regression model 180 after it has been trained, as will be discussed in more detail below.

After the computer device 50 obtains the training dataset 15a, a first machine learning algorithm 120 may be performed on the training dataset 15a to identify a plurality of key factors 125 that affect the actual offset value of the exposure tool 10. In the embodiment, the step of performing the first machine learning algorithm 120 may include using an analytical model 122 to select a plurality of factors from the training dataset 15a that affect the actual offset value, and using a voting model 124 to identify the key factors 125 from the selected factors. More specifically, the computer device 50, through the analytical model 122, initially selects factors from the training dataset 15a that influence the actual offset value, and the voting model 124, consisting of multiple sub-analysis models, decides whether the factors selected by the analytical model 122 are the key factors 125 based on a majority vote. In the embodiment, the analytical model 122 may include a decision tree analysis model. In the embodiment, the voting model 124 may include a random forest model. In the embodiment, the key factors 125 selected by the voting model 124 may include lens temperature, mask density, and pattern source.

After the computer device 50 selects the key factors 125, a second machine learning algorithm 135 is performed on the key factors 125 (more specifically, on the portion of the training dataset 15a that corresponds to the key factors 125) to obtain an input dataset 150. In the embodiment, the step of performing the second machine learning algorithm 135 further includes extracting features from the portion of the training dataset 15a that corresponds to the key factors 125 using a feature extraction model 145 to obtain a feature matrix, and then flattening the feature matrix into a one-dimensional matrix to obtain the input dataset 150. In the embodiment, the portion of the training dataset 15a that corresponds to the key factors may contain two-dimensional or higher-dimensional information, so the second machine learning algorithm 135 may extract features from it and convert them into a one-dimensional matrix that may be used by the subsequent regression model 180, i.e., the input dataset 150. In the embodiment, the feature extraction model 145 includes a CNN model.

After the computer device 50 obtains the input dataset 150, the input dataset 150 is used to train the regression model 180 to obtain the predicted offset value. In the embodiment, the step of performing the training of the regression model 180 using the input dataset 150 further includes first performing a third machine learning algorithm 160 on the input dataset 150 to obtain a labeled input dataset 170, and then using the labeled input dataset 170 to train the regression model 180. In the embodiment, the step of performing the third machine learning algorithm 160 further includes first performing a domain transformation process 162 on the input dataset 150 to convert the input dataset 150 into a high-dimensional matrix, then classifying the input dataset 150 and adding labels using a classification model 165, and subsequently performing another domain transformation process 167 on the labeled input dataset 150, converting the labeled input dataset 150 back into a one-dimensional matrix to obtain the labeled input dataset 170. The steps of performing the third machine learning algorithm 160 by the computer device 50 may be used for further interpretation of the data in the regression model 180, such as deriving results indicating that data from specific categories deviate more from the main data set in the regression model 180 after human interpretation. In the embodiment, the steps of performing the third machine learning algorithm 160 may further include using an optional fully connected model 175 to recombine the features of the labeled input dataset 170 to attempt to identify new features.

Subsequently, after the computer device obtains the labeled input dataset 170, it uses the labeled input dataset 170 to train the regression model 180, thereby obtaining the predicted offset value 185. Then, a loss function is used to compute the loss value between the predicted offset value and the actual offset value, and the parameters of the regression model 180 are optimized based on the loss value. In the embodiment, loss functions such as Mean Squared Error (MSE), Mean Absolute Error (MAE), or Cross-Entropy may be used to calculate the loss value between the predicted offset value and the actual offset value. Furthermore, an optimizer recursively adjusts the parameters of the regression model 180 (e.g., the weights of a polynomial regression model) to minimize the loss value, thereby optimizing the regression model 180. The optimizer may implement algorithms such as Gradient Descent, Stochastic Gradient Descent, or Adaptive Moment Estimation (Adam). For example, an optimizer using Gradient Descent computes the gradient of the loss function and adjusts the machine learning model's parameters based on the gradient in order to reduce the loss value. Through repeated feedback of results and parameter updates during the training process, the loss value is gradually reduced until it converges to a minimum. In the embodiment, the learning rate of the Gradient Descent algorithm is 0.01. In the embodiment, the regression model is a polynomial regression model. In the embodiment, the loss value is computed using Mean Squared Error.

Subsequently, after optimizing the parameters of the regression model 180, the computer device 50 may use the validation dataset 15b to validate the regression model 180. In the embodiment, after the computer device 50 optimizes the parameters of the regression model 180, the validation dataset 15b is unfolded into a one-dimensional matrix, and the validation dataset 15b is used in the trained regression model 180 to obtain the validation offset value for the validation dataset 15b. The validation offset value is used to validate the difference between the predicted offset value 185 and the validation offset value. For example, if the difference between the validation offset value and the predicted offset value 185 is less than 10%, the regression model 180 may be considered as the trained regression model 180.

Subsequently, in step 320, the trained regression model 180 is used to calculate the predicted offset value 185 for the exposure tool 10, meaning the computer device 50 may use the test dataset 15c to test the regression model. In the embodiment, after the computer device 50 confirms that the difference between the validation offset value and the predicted offset value 185 is smaller than a specified value, the test dataset 15c is unfolded into a one-dimensional matrix, and the test dataset 15c is used in the trained regression model 180 to obtain the predicted offset value 185 corresponding to the test dataset 15c.

Next, referring to step 330 in FIG. 3 and in conjunction with FIG. 4, after obtaining the predicted offset value 185, the predicted offset value 185 is used to compensate for the exposure position of the exposure tool 10 (e.g., compensating for the exposure position of the tested wafer 20), thereby adjusting the exposure position of the exposure tool 10 to compensate for the thermal aberration D of the exposure tool 10.

After confirming that the imaging of the tested wafer 20, following compensation of the exposure position, yields satisfactory results, the regression model 180 may be applied to actual product production. More specifically, prior to actual production, exposure tests are conducted on the exposure tool 10 using the tested wafer 20, and the relevant data is used in the regression model 180 to obtain the predicted offset value 185 (in other words, the relevant data of the tested wafer 20 is used as the test data set 15c). Subsequently, the exposure tool 10 compensates the exposure position of the actual production wafers using this predicted offset value 185. Furthermore, the relevant data of the tested wafer 20 may be periodically used as the raw data 12 to retrain the regression model 180, thereby updating the parameters of the regression model 180 to address the growth limitations encountered by the original physical model. It should be understood that compensating for the exposure position involves adjustments to various tool parameters of the exposure tool 10, not simply a shift of the expected exposure position. Therefore, for simplicity, the actual adjustment process is omitted.

In summary, the embodiment of the present disclosure analyzes potential factors contributing to thermal aberrations caused by the exposure tool 10 using machine learning algorithms. It extracts the features of these factors from the raw data to train the regression model, thereby improving the scalability issues of the regression model. This reduces the development time for semiconductor devices and improves yield, thus minimizing resource waste during the semiconductor device manufacturing process. It should be understood that not all advantages have been necessarily discussed here, and not all embodiments require specific advantages, and other embodiments may offer different advantages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for determining an exposure position of an exposure tool, performed by a computer device, comprising:
training a regression model based on a raw data of the exposure tool with a plurality of key factors, wherein the key factors affect an actual offset value of the exposure tool;
using the trained regression model to calculate a predicted offset value based on the raw data; and
compensating for the exposure position of the exposure tool based on the predicted offset value to adjust the exposure position of the exposure tool.

2. The method as claimed in claim 1, wherein the training of the regression model further comprises:
performing a preprocessing procedure on the raw data to obtain a training dataset;
performing a first machine learning algorithm to the training dataset to obtain the key factors affecting the actual offset value of the exposure tool;
performing a second machine learning algorithm to the key factors of the training dataset to obtain an input dataset;
using the input dataset to train the regression model to obtain the predicted offset value; and
calculating a loss value between the predicted offset value and the actual offset value using a loss function, and optimizing parameters of the regression model based on the loss value.

3. The method as claimed in claim 2, wherein performing the first machine learning algorithm further comprises:
selecting a plurality of factors affecting the actual offset value of the training dataset using an analytical model; and
selecting the key factors from the factors affecting the actual offset value using a voting model.

4. The method as claimed in claim 3, wherein the analytical model includes a decision tree analysis model, and the voting model includes a random forest model.

5. The method as claimed in claim 2, wherein performing the second machine learning algorithm further comprises:
extracting features from the key factors using a feature extraction model to obtain a feature matrix; and
flattening the feature matrix into a one-dimensional matrix to obtain the input dataset.

6. The method as claimed in claim 5, wherein the feature extraction model includes a convolutional neural network model.

7. The method as claimed in claim 2, wherein using the input dataset to train the regression model further comprises:
performing a third machine learning algorithm to the input dataset to obtain a labeled input dataset; and
using the labeled input dataset to train the regression model.

8. The method as claimed in claim 7, wherein performing the third machine learning algorithm further comprises:
performing a domain transformation process on the input dataset, converting the input dataset into a high-dimensional matrix;
classifying the input dataset using a classification model and adding labels; and
performing another domain transformation process on the input dataset, converting the input dataset into a one-dimensional matrix to obtain the labeled input dataset.

9. The method as claimed in claim 7, wherein performing the third machine learning algorithm further comprises:
using a fully connected model to recombine features of the labeled input dataset.

10. The method as claimed in claim 2, wherein optimizing the parameters of the regression model based on the loss value further comprises:
adjusting the parameters of the regression model using a gradient descent method to minimize the loss value.

11. The method as claimed in claim 2, wherein the key factors comprise: lens temperature, mask density, and pattern source.

12. The method as claimed in claim 2, further comprising:
performing a k-fold cross-validation on the raw data to obtain the training dataset.

13. The method as claimed in claim 2, wherein the regression model is a polynomial regression model, and the loss value is a mean squared error.

14. The method as claimed in claim 2, wherein performing the preprocessing procedure further comprises:
obtaining a validation dataset and flattening the validation dataset into a one-dimensional matrix; and
using the validation dataset on the trained regression model to obtain a validation offset value, wherein the validation offset value is used to validate the difference with the predicted offset value.

15. The method as claimed in claim 2, wherein performing the preprocessing procedure further comprises:
obtaining a test dataset and flattening the test dataset into a one-dimensional matrix;
using the test dataset on the trained regression model to obtain the predicted offset value; and
using the predicted offset value to compensate for the exposure position of the exposure tool.

16. The method as claimed in claim 2, wherein performing the preprocessing procedure further comprises performing a standardization process and an encoding procedure on the raw data.

17. A computer device implementing the method of claim 1, wherein the computer device uses the predicted offset value obtained by the method to compensate for the exposure position of the exposure tool.

18. The computer device as claimed in claim 17, wherein the training of the regression model further comprises:
performing a preprocessing procedure on the raw data to obtain a training dataset;
performing a first machine learning algorithm to the training dataset to obtain the key factors affecting the actual offset value of the exposure tool;
performing a second machine learning algorithm to the key factors of the training dataset to obtain an input dataset;
using the input dataset to train the regression model to obtain the predicted offset value; and
calculating a loss value between the predicted offset value and the actual offset value using a loss function, and optimizing parameters of the regression model based on the loss value.

19. The computer device as claimed in claim 18, wherein performing the first machine learning algorithm further comprises:
selecting a plurality of factors affecting the actual offset value of the training dataset using an analytical model; and
selecting the key factors from the factors affecting the actual offset value using a voting model.

20. The computer device as claimed in claim 18, wherein the key factors comprise: lens temperature, mask density, and pattern source.
